(19) United States
(12) Patent Application Publication
(10) Pub. No.: US 2011/0248738 A1
(43) Pub. Date: Oct. 13, 2011

(54) TESTING APPARATUS FOR ELECTRONIC DEVICES

(76) Inventors: Chak Tong SZE, Kwai Chung (HK); Pei Wei TSAI, Kwai Chung (HK); Tin Yi CHAN, Kwai Chung (HK); Wai Hong SIZTO, Kwai Chung (HK); Cho Hin CHEUK, Kwai Chung (HK)

(21) Appl. No.: 13/079,074

(22) Filed: Apr. 4, 2011

Related U.S. Application Data
(60) Provisional application No. 61/322,961, filed on Apr. 12, 2010.

(51) Int. Cl. G01R 31/20; H01L 21/677

(52) U.S. Cl. 324/757.03; 414/225.01; 414/226.01

(57) ABSTRACT

A wafer processing apparatus used for the testing of electronic devices comprises first and second clampers movably mounted on a shaft, each clamper being configured for holding a wafer carrier on which a wafer is mounted. Clamping fingers on each of the first and second clampers are operative to clamp onto the wafer carrier to hold the wafer carriers, and the clampers are operative to move the wafer carriers reciprocally between a loading position and a wafer processing location for processing the wafers.

### FIELD OF THE INVENTION

The invention relates to a testing apparatus for electronic devices, in particular semiconductor units such as light-emitting devices (“LEDs”).

### BACKGROUND AND PRIOR ART

Traditional wafer tables are designed such that wafer rings on which wafers are mounted are slotted in sideways onto the wafer table for holding the wafer during detachment of electronic devices held on the wafer. The wafer table may also stretch an adhesive film on the wafer ring so that the wafer being held by the adhesive film is expanded and its semiconductor units are spaced apart. In the conventional design, this means that wafer rings must be removed by pulling the wafer ring out from the wafer table sideways. The wafer ring is then slid to a magazine slot for unloading, before a new wafer is sequentially removed from the next slot for inserting to the wafer table. Accordingly, the wafer loading and unloading operations cannot be parallel.

Further, in a conventional pick arm for picking up and placing electronic devices such as LEDs, the pick arm either rotates or moves linearly such as up and down for positioning the electronic devices. For pick arms that require motion in more than one axis, one of the actuators (such as a motor) is commonly mounted over the moving part. Therefore, the weight of the moving part is heavy, and the weight and movement of the pick arm in only one axis is a constraint on the performance of the machine.

Additionally, conventional test contactor designs at testing stations have certain shortfalls. One example of a conventional design is an integrated contactor with package support for supporting the package. When the package support is indexed to the test station, an actuator pushes the device together with the package support and contactor to a top plate for testing. This design has the disadvantage of requiring multiple test contactors, each having different electrical characteristics to conduct testing. Thus, the test results from different contactors may vary.

Another conventional test contactor design has a fixed top plate with an opening at the test station. A turret table has multiple package supports incorporated into the turret table to hold electronic devices. This design allows only a small gap between the rotary turret table and the top plate. When the device is indexed to the test station, the contactor pushes the device up to a top plate position for testing. When the test is completed, the contactor moves down and the turret table indexes to the next package support position. However, this design does not allow units with lenses to be tested because the small gap between the top plate and the turret table may tend to scratch and damage the lens.

### SUMMARY OF THE INVENTION

It is thus an object of the invention to seek to provide a testing apparatus which avoids at least some of the aforesaid shortcomings of the prior art.

According to a first aspect of the invention, there is provided wafer processing apparatus comprising: first and second clampers movably mounted on a shaft, each clamper being configured for holding a wafer carrier on which a wafer is mounted; and clamping fingers on each of the first and second clampers that are operative to clamp onto the wafer carrier to hold the wafer carriers; wherein the clampers are operative to move the wafer carriers reciprocally between a loading position and a wafer processing location for processing the wafers.

According to a second aspect of the invention, there is provided a pick-arm assembly for electronic devices, comprising: a first pick arm and a second pick arm; a rotary motor located above the first and second pick arms which is operative to drive the first and second pick arms to rotate about a rotary axis; first and second linear drivers located over the rotary motor for driving the first pick arm and the second pick arm respectively; a first linkage operatively connecting the first pick arm to the first linear driver and a second linkage operatively connecting the second pick arm to the second linear driver, the first and second linkages being operative to guide the first and second pick arms to move linearly parallel to the rotary axis.

According to a third aspect of the invention, there is provided an automated testing system for electronic devices, comprising: a plurality of carriers configured for carrying electronic devices to be tested; a rotary turret on which the plurality of carriers are attached to move the carriers together with the electronic devices to a testing location; a top plate at the testing location on which testing instruments are mounted for testing the electronic devices; a contactor located at the testing location; and a push-up motor operatively connected to the contactor for pushing the contactor together with the electronic device towards the top plate for testing a characteristic of the electronic device.

It will be convenient to hereinafter describe the invention in greater detail by reference to the accompanying drawings. The particularity of the drawings and the related description is not to be understood as superseding the generality of the broad identification of the invention as defined by the claims.

### BRIEF DESCRIPTION OF THE DRAWINGS

FIG. 1 is an isometric top view of a wafer exchange arm assembly according to the preferred embodiment of the invention for transferring wafers to and from a wafer table;

FIG. 2 is an isometric bottom view of the wafer exchange arm assembly;

FIG. 3 is a front view of the wafer exchange arm assembly;

FIG. 4 is an enlarged side view of a clamping finger of the wafer exchange arm assembly;

FIGS. 5A and 5B are plan views of a wafer clamp subassembly showing its clamping fingers in opened and closed positions respectively;

FIG. 6 is an isometric view of the wafer table illustrating a mechanism for holding a wafer ring and expanding an adhesive film of the wafer ring;

FIG. 7 is a side view of the wafer table;

FIG. 8 is an isometric view of a dual pick-arm assembly according to the preferred embodiment of the invention;

FIG. 9 is a front view of the dual pick-arm assembly;

FIG. 10 is a side view of the dual pick-arm assembly looking from direction A of FIG. 9;

FIG. 11 is a cross-sectional front view of the dual pick-arm assembly;

FIG. 12 is an isometric view of a testing system according to the preferred embodiment of the invention including a turret table;

FIG. 13 is an enlarged plan view of a unit carrier incorporated in the turret;

FIG. 14 is an enlarged plan view of a top plate for mounting testing instruments for the semiconductor units;

FIG. 15 is a side view of a contactor according to the preferred embodiment of the invention;

FIG. 16 is a side view of a clamping assembly of the contactor; and

FIG. 17 is a plan view of the contactor.

### DETAILED DESCRIPTION OF THE PREFERRED EMBODIMENT OF THE INVENTION

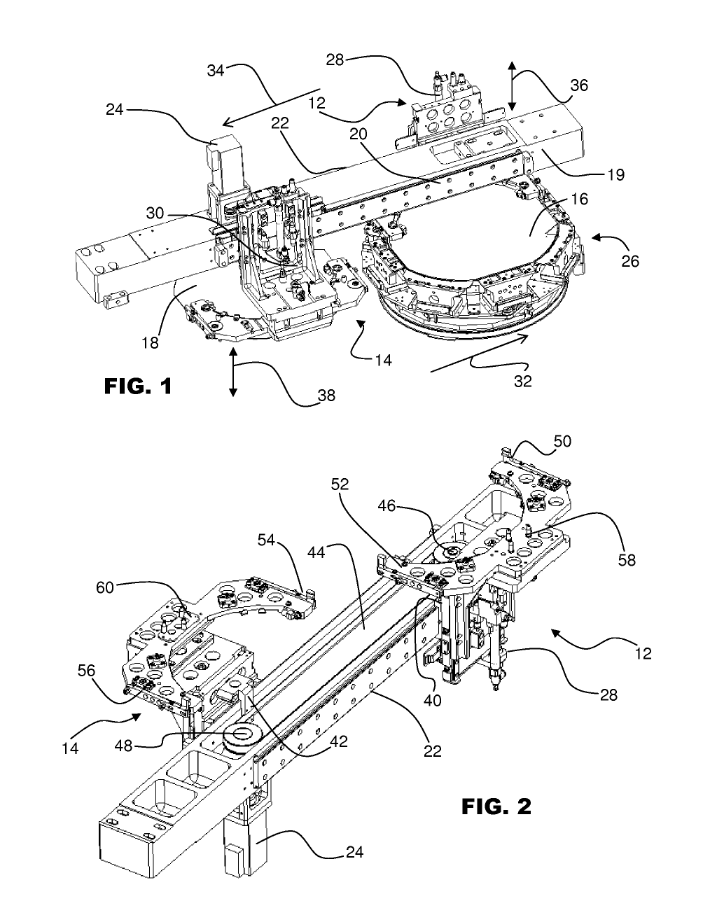

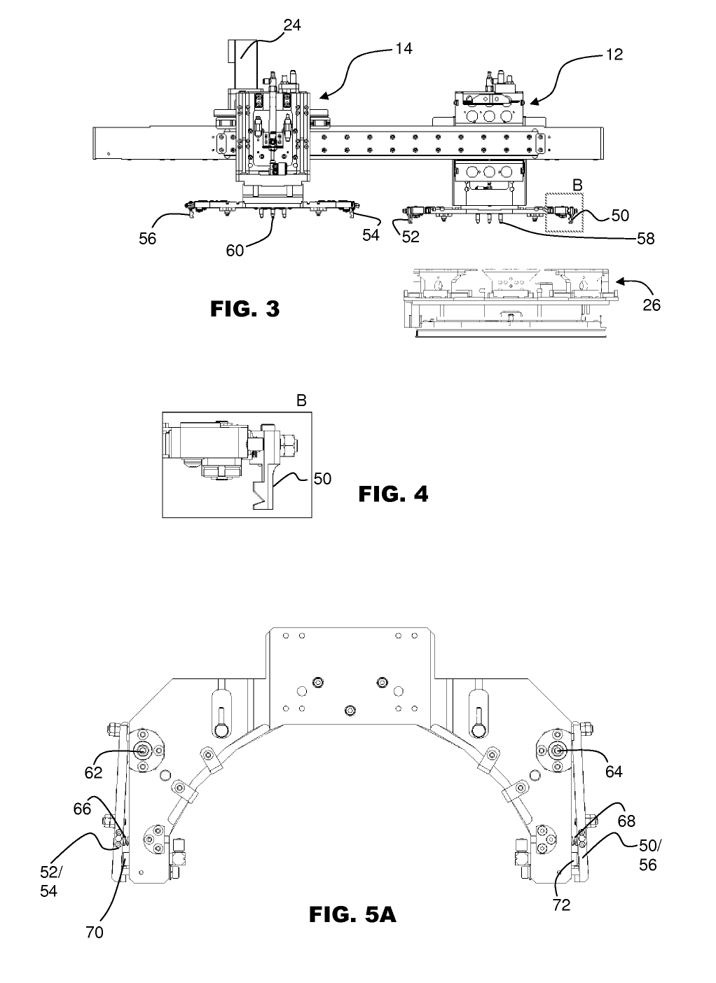

FIG. 1 is an isometric top view of a wafer exchange arm assembly according to the preferred embodiment of the invention for transferring wafers between a loading position and a wafer table 26 at a wafer processing location. The wafers are mounted on wafer carriers 16, 18. FIG. 2 is an isometric bottom view of the wafer exchange arm assembly, whereas FIG. 3 is a front view of the wafer exchange arm assembly.

There are two clampers 12, 14 fixed on a timing belt 44 by clamps 42, 40. The clampers are connected to and driven to move by a single motor 24 via timing pulleys 46, 48 to which the timing belt 44 is connected. The clampers 12, 14 are movable along linear motion guides 20, 22 for guiding their linear motions. Each of the clampers 12, 14 is equipped with a height actuator such as a double-acting pneumatic cylinder 28, 30 for raising or lowering the clampers 12, 14. All of the aforesaid devices are mounted on a carriage shaft 19.

The clampers 12, 14 are operative to move the wafer carriers 16, 18 reciprocally between the loading position and the wafer processing location where the wafer table 26 is situated. In other words, one clamper 12 may be transferring a wafer carrier 16 to the wafer table 26 while the other clamper 14 is transferring another wafer carrier 18 to the loading position.

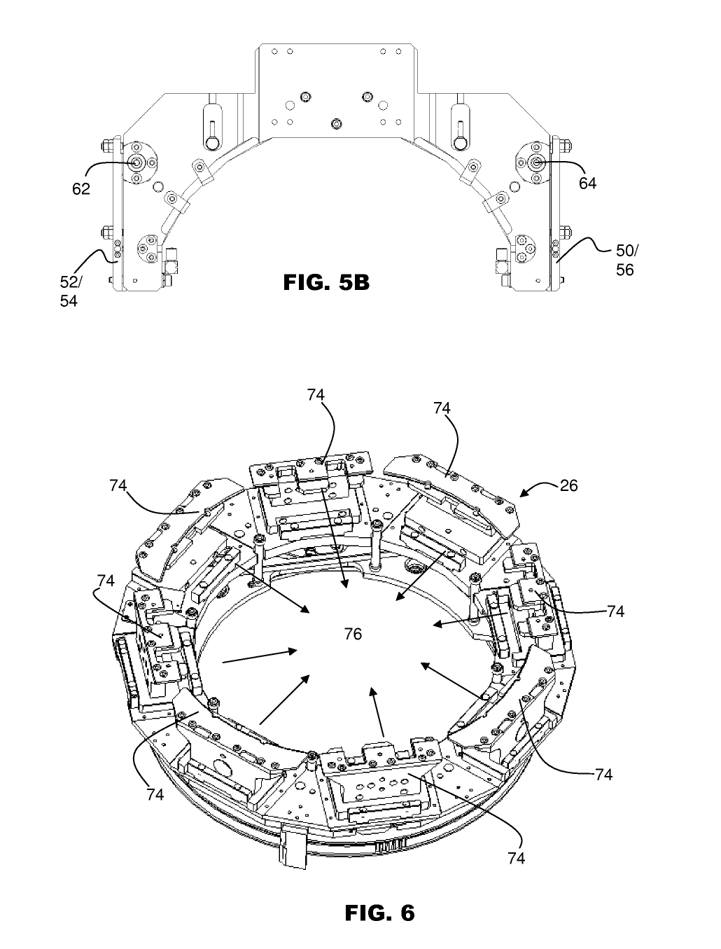

The mechanism of the wafer clamping design can be seen in more detail in FIG. 4, FIG. 5A and FIG. 5B. FIG. 4 is an enlarged side view of a clamping finger 50 of the wafer exchange arm assembly. FIGS. 5A and 5B are plan views of a wafer clamp subassembly showing its clamping fingers 50, 52, 54, 56 in opened and closed positions respectively.

There are two pairs of clamping fingers 50, 52 and 54, 56. A V-shaped groove is incorporated into a clamping region of each finger 50, 52, 54, 56, one of which is shown in close-up in FIG. 4. This design is useful for self-alignment of the wafer when the clamping position is not precise. This geometry of the V-shaped groove can guide the wafer to a stable position to be carried when the clamping fingers clamp onto the wafer carrier 16, 18.

The clamping fingers 50, 52, 54, 56 are pivoted with respect to each clamper 12, 14 via bearings 62, 64. The opening of the two pairs of clamping fingers 50, 52, 54, 56 is driven by deflection actuators in the form of extendable pneumatic pistons 70, 72 which cause turning moments about the bearings 62, 64. The closing of the clamping fingers to clamp the wafer carrier 16, 18 is actuated by releasing the pressure from the pneumatic pistons 70, 72 and using a spring return mechanism 66, 68 to close the clamping fingers while holding the wafer carriers 16, 18 with balancing pins 58, 60.

A specially-designed wafer table 26 with wafer locks 74 driven by the pneumatic pistons 70, 72 is used to hold wafers. It is also equipped with the function of expanding a mylar film on which a wafer substrate is mounted. The locks 74 move in an expanding direction 84 when it is driven by a belt drive mechanism 80 and screw 82 via a gear 78 (see FIG. 7).

The following is a description of the mechanisms in operation. When an exchanging process of the wafers is needed, the exchange arm is triggered to perform the process. At the start of the process, it is assumed that there is no wafer held by the clampers 12, 14. The motor 24 starts to drive the timing pulley 48 which turns the timing belt 44. As the two clampers 12, 14 are fixed on the same timing belt, the clampers 12, 14 are moved simultaneously 32, 34 to their target positions. Once the clampers 12, 14 are at their target positions, that is, above a processed wafer on one wafer carrier 16 on the wafer table 26 and an unprocessed wafer on another wafer carrier 18 respectively, the mechanisms of the clamping fingers 50, 52, 54, 56 are at opened positions (FIG. 5A).

In order to grip onto the wafer carrier 16 holding the processed wafer and the wafer carrier 18 holding the unprocessed wafer, the pneumatic cylinders 28, 30 are triggered to push the clampers 12, 14 downward 36, 38. At this time, the mechanisms of the clamping fingers 50, 52, 54, 56 are actuated to closed positions (FIG. 5B) to hold the wafers as in FIG. 1. The balancing pins 58, 60 are used to balance the wafers in case the positions of the clamping fingers do not clamp at the position of the centre of gravity of the wafer. This can avoid causing a tilting moment that may make the wafer fall.

FIG. 6 is an isometric view of the wafer table 26 illustrating the mechanism for holding a wafer ring and expanding an adhesive film of the wafer ring. FIG. 7 is a side view of the wafer table 26. When the unprocessed wafer 18 reaches the top of the wafer table 26, the wafer locks 74 are opened to allow the clamper 14 holding the wafer 18 to move down. Once the wafer 18 is moved down 36 by the double-acting pneumatic cylinder 30, the locks 74 are closed 76 to hold the wafer 18 and the clamping fingers 54, 56 of the clamp open to release the wafer 18. The clamp is then moved up 36, 38 and the expanding mechanism 84 is triggered to expand the wafer 18 for picking up semiconductor units from the wafer 18.

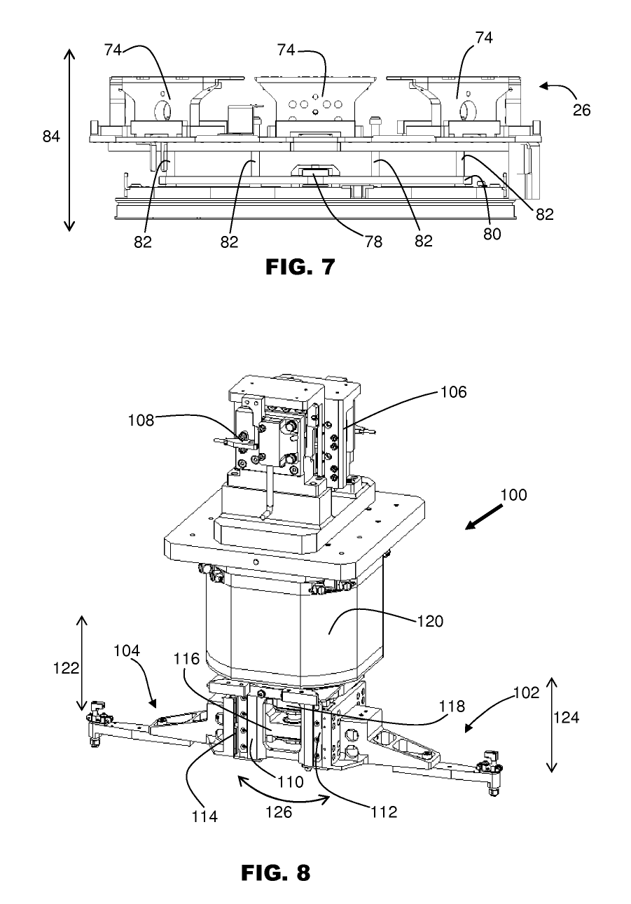

The apparatus also provides a dual pick-arm assembly 100. FIG. 8 is an isometric view of a dual pick-arm assembly 100 according to the preferred embodiment of the invention. A carriage 110 is installed below the rotary motor 120. Linear motion guides 112, 114 are fixed on the two opposite sides of the carriage 110. First and second pick arms 102, 104 are attached on the linear motion guides 112, 114 which guide vertical motion of the pick arms 102, 104. Two paddle-like bearing housings 116, 118 with rotational ball bearings 128, 130 are attached to the two picks arms 102, 104.

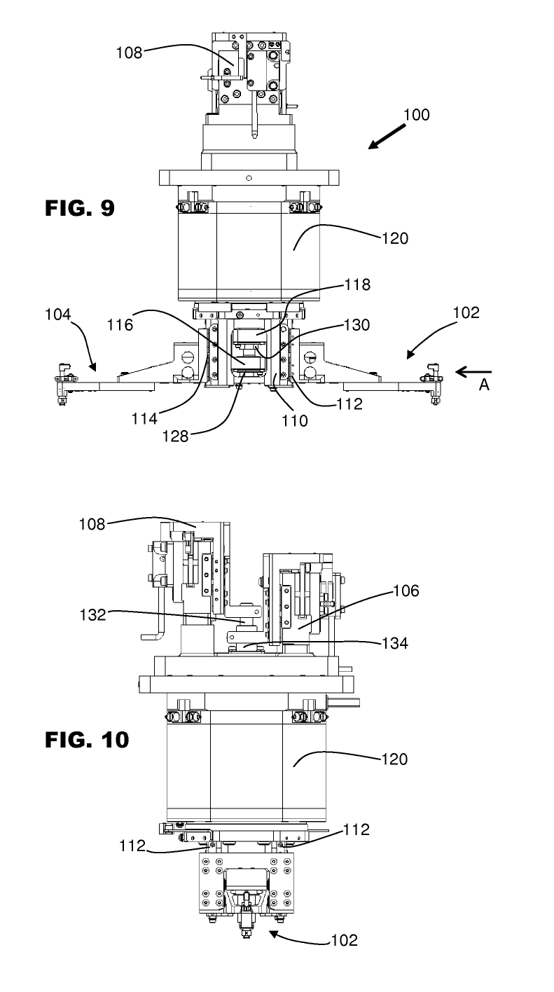

FIG. 9 is a front view of the dual pick-arm assembly. FIG. 10 is a side view of the dual pick-arm assembly looking from direction A of FIG. 9. The two bearings 128, 130 are concentric with the centre of the rotary motor 120 but they are not at the same height level as shown in FIG. 9.

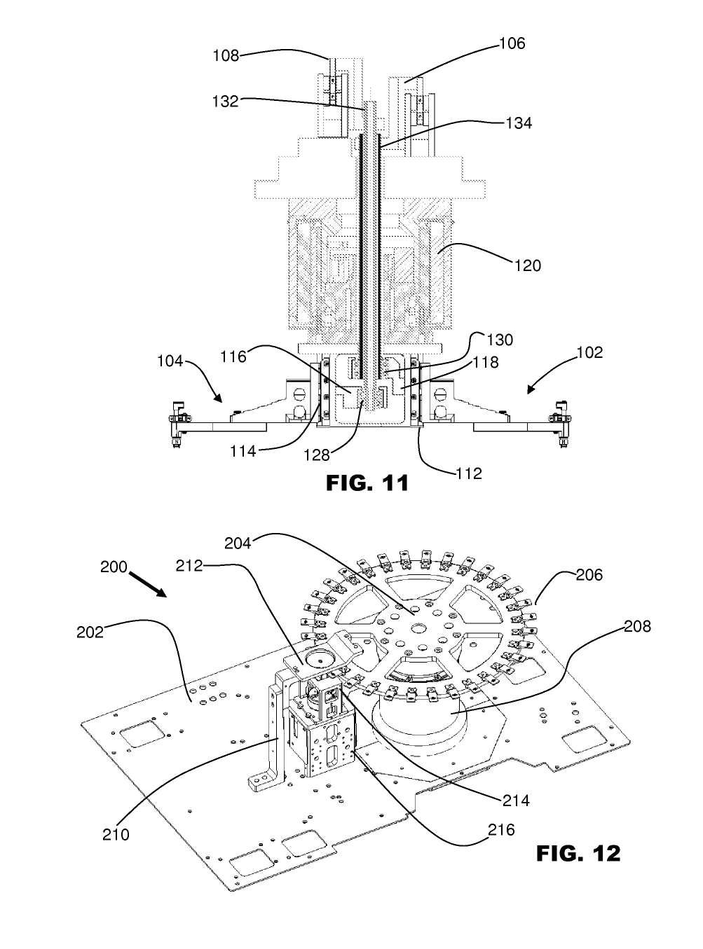

FIG. 11 is a cross-sectional front view of the dual pick-arm assembly 100. Two linkages, which may be in the form of thin-walled cylinders 132, 134 with different diameters, pass through the centre of the rotary motor 120 and are fixed on inner rings of two bearing systems 128, 130. As their outer diameters are not the same, the smaller cylinder 132 is inserted into and is located within the larger cylinder 134. The other ends of the two cylinders 132, 134 are correspondingly clamped onto linear motors 106, 108 which are installed on top of the rotary motor 120. The thin-walled cylinders 132, 134 connect each pick arm 102, 104 to a respective linear motor 106, 108 to guide the pick arms 102, 104 to move linearly in opposite directions parallel to a rotary axis of the rotary motor 120. The rotary axis is located between the two pick arms 102, 104.

The rotary motor 120 is used for rotating the carriage 110 when the two pick arms 102, 104 need to transfer semiconductor units from one location to another. The rotary motor 120 is operable to drive the pick arms 102, 104 to rotate about the rotary axis. The function of picking and placing semiconductor units is achieved by the independent first and second pick arms 102, 104 which are driven vertically by the two linear motors 106, 108 via the thin-walled cylinders 132, 134. The bearing systems 128, 130 serve to decouple the rotary function 126 and vertical driving function 122, and guide the pick arms 102, 104 to rotate.

Furthermore, there is a testing system 200 where semiconductor units can be tested. FIG. 12 is an isometric view of a testing system 200 according to the preferred embodiment of the invention including a turret table 204. It is an automatic testing system and includes two main modules. The main modules comprise a turret table 204 that has a plurality of carriers 206 attached to it for carrying electronic devices such as semiconductor units, and a vertically-movable contactor 214, 216 located at a testing location. When a semiconductor unit is placed onto the carrier 206 of the turret table 204, the turret motor 208 drives the turret table 204 to rotate the carrier 206 to a position on top of the contactor 214.

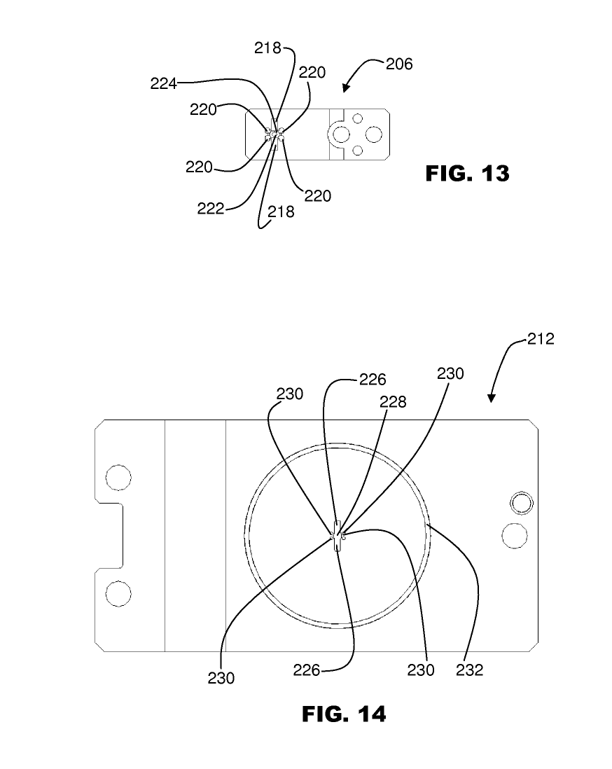

FIG. 13 is an enlarged plan view of a unit carrier 206 incorporated in the turret table 204. There are several slots, including a contact slot 220 for inserting contact strips 234, clamping slots 218 for inserting clamping fingers 236, and vacuum slot 224 for inserting the vacuum holder 240 through the carrier 206 to communicate with a semiconductor unit placed on it.

FIG. 14 is an enlarged plan view of a top plate 212 for mounting testing instruments for testing the semiconductor units. The top plate 212 is held by a stand 210 and is mounted with an integrated sphere (not shown) at a sphere mounting location 232. There are also push-up slots 226, 228, 230 located centrally at the sphere mounting location 232 for further pushing up 252 the semiconductor units for testing utilizing the integrated sphere.

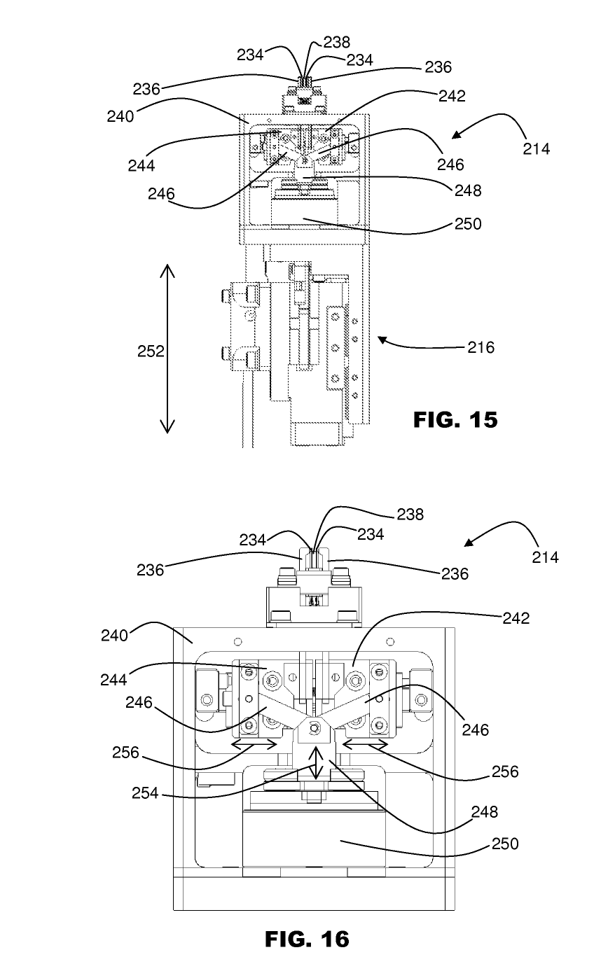

FIG. 15 is a side view of the contactor 214 according to the preferred embodiment of the invention. The contactor 214 has two major parts. There is a clamping assembly 236 for stabilization and precising of the semiconductor unit.

There is also a linear motor 250 operatively connected to the contactor 214 for driving the contactor 214 in directions towards or away from the top plate 212, and in particular, for pushing up 252 the contactor 214 with a semiconductor unit for testing.

FIG. 16 is a side view of a clamping assembly 236 of the contactor 214. The clamping assembly 236 of the contactor 214 is shown in further detail. The clamping assembly 236 consists of two vertical clamping fingers. Each of the vertical clamping fingers is fixed on a block with linear motion guides 242, 244 contained in a carriage 240. The allowable moving direction 256 of the vertical clamping fingers is perpendicular to the length of the clamping fingers of the clamping assembly 236. Two linkage bars 246 are connected to the two linear motion guides 242, 244 accordingly. The other ends of the linkage bars 246 are connected together with a single bar 248 in a V-shape configuration.

The single bar 248 is fixed on a platform and is drivable by the linear voice coil motor 250. When the linear voice coil motor 250 pulls down the bar 248, it drives the V-shaped linkage bars 246 to move towards each other 256. That makes the clamping assembly 236 close onto and hold the unit. On the other hand, when the linear voice coil motor 250 pushes up the bar 254, it makes the clamping assembly 236 open. Also, there is a vacuum holder 238 at the centre of the clamp 236 to assist in securing the semiconductor unit on the contactor 214.

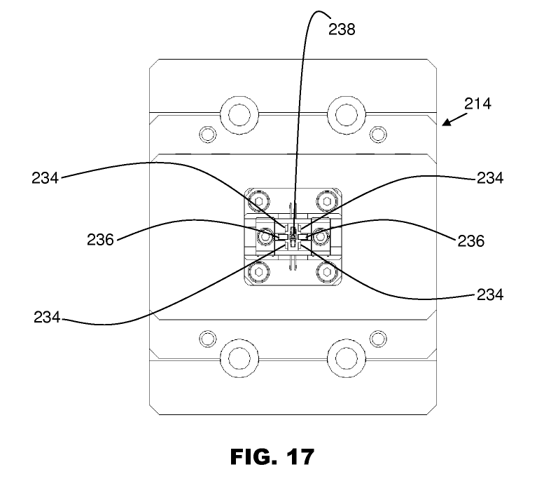

FIG. 17 is a plan view of the contactor 214. Once the semiconductor unit is placed on a support surface 222 of the carrier 206, the turret motor 208 rotates. When the carrier 206 with the semiconductor unit arrives at the top of the contactor 214, the linear motor 250 moves the contactor 214 up to make the contactor 214 touch the bottom of the semiconductor unit. As there is a vacuum suction force from the vacuum holder 238, the unit is sucked securely onto the carrier 206. The linear voice coil motor 250 then pulls down 254 the single bar 248 to trigger the V-bar mechanism 246 to make the clamp 236 hold the semiconductor unit with the contactor 234 and to precise its position.

After holding the unit securely, the linear motor 250 pushes up the contactor 214 further to penetrate the carrier 206 through the various slots 218, 220, 224 of the carrier 206 and the push-up slots 226, 228, 230 of the top plate 212 for testing using the integrated sphere.

The invention described herein is susceptible to variations, modifications and/or additions other than those specifically described and it is to be understood that the invention includes all such variations, modifications and/or additions which fall within the spirit and scope of the above description.

1. Wafer processing apparatus comprising:
first and second clampers movably mounted on a shaft, each clamper being configured for holding a wafer carrier on which a wafer is mounted; and
clamping fingers on each of the first and second clampers that are operative to clamp onto the wafer carrier to hold the wafer carriers;
wherein the clampers are operative to move the wafer carriers reciprocally between a loading position and a wafer processing location for processing the wafers.

2. Wafer processing apparatus as claimed in claim 1, wherein one clamper is operative to transfer a wafer carrier to the wafer processing location while the other clamper is transferring another wafer carrier to the loading position.

3. Wafer processing apparatus as claimed in claim 2, further comprising a motor connected to the first and second clampers, the motor being operative to drive the first and second clampers to move in opposite directions.

4. Wafer processing apparatus as claimed in claim 3, further comprising a timing belt on which the first and second clampers are fixed, wherein the timing belt is connected to the motor via timing pulleys.

5. Wafer processing apparatus as claimed in claim 1, wherein the shaft comprises a linear guide on which the first and second clampers are mounted for guiding linear motion of the first and second clampers.

6. Wafer processing apparatus as claimed in claim 1, wherein each clamping finger has a V-shaped groove for clamping onto the wafer carrier and for guiding the wafer carrier to a stable position to be carried.

7. Wafer processing apparatus as claimed in claim 1, further comprising a height actuator for actuating the clamper to be raised or lowered with respect to the shaft.

8. Wafer processing apparatus as claimed in claim 1, wherein the clamping fingers are pivoted with respect to the clamper, and the clamper further comprises a deflection actuator to move the clamping fingers relative to the clamper to clamp or release the wafer carrier.

9. Pick-arm assembly for electronic devices, comprising:
a first pick arm and a second pick arm;
a rotary motor located above the first and second pick arms which is operative to drive the first and second pick arms to rotate about a rotary axis;
first and second linear drivers located over the rotary motor for driving the first pick arm and the second pick arm respectively;
a first linkage operatively connecting the first pick arm to the first linear driver and a second linkage operatively connecting the second pick arm to the second linear driver, the first and second linkages being operative to guide the first and second pick arms to move linearly parallel to the rotary axis.

10. Pick arm assembly as claimed in claim 9, wherein first and second pick arms are located on opposite sides of the rotary motor such that the rotary axis is located between the first and second pick arms.

11. Pick arm assembly as claimed in claim 9, further comprising a carriage installed below the rotary motor on which linear motion guides supporting the first and second pick arms are mounted.

12. Pick arm assembly as claimed in claim 11, further comprising first and second rotational bearing systems located in the carriage which are attached to the first and second pick arms to guide the pick arms to rotate.

13. Pick arm assembly as claimed in claim 9, wherein the first and second linkages comprise thin-walled cylinders which pass through a center of the rotary motor and which are clamped to the respective first and second linear drivers.

14. Pick arm assembly as claimed in claim 13, wherein the first linkage comprises a cylinder having a smaller diameter than a cylinder of the second linkage, and the first linkage is located within the second linkage.

15. Automated testing system for electronic devices, comprising:
a plurality of carriers configured for carrying electronic devices to be tested;
a rotary turret on which the plurality of carriers are attached to move the carriers together with the electronic devices to a testing location;
a top plate at the testing location on which testing instruments are mounted for testing the electronic devices;
a contactor located at the testing location; and
a push-up motor operatively connected to the contactor for pushing the contactor together with the electronic device towards the top plate for testing a characteristic of the electronic device.

16. Automated testing system as claimed in claim 15, wherein the top plate further comprises a push-up slot which is shaped and configured to receive the electronic device through the push-up slot when the electronic device is pushed by the contactor.

17. Automated testing system as claimed in claim 15, wherein the contactor includes a clamping assembly comprising clamping fingers which are operative to extend through clamping slots in the top plate to clamp onto the electronic device for stabilizing and precising the electronic device.

18. Automated testing system as claimed in claim 17, further comprising linkage bars connecting the clamping fingers to a linear actuator, wherein actuation of the linear motor moves the clamping fingers in directions perpendicular to a length of each clamping finger.

19. Automated testing system as claimed in claim 15, wherein the push-up motor comprises a linear motor operatively connected to the contactor for raising or lowering the contactor in directors towards or away from the top plate.

20. Automated testing system as claimed in claim 15, wherein the carrier includes a contact slot for inserting an electrically-conductive contact of the contactor, and clamping slots for inserting clamping fingers of a clamping assembly that is operative to clamp onto the electronic device during testing, through the contact slot and clamping slots respectively.
